(19) United States
(12) Patent Application Publication
(10) Pub. No.: US 2013/0266032 A1
(43) Pub. Date: Oct. 10, 2013

(54) Laser architectures

(71) Applicant: REALD INC., Beverly Hills, CA (US)

(72) Inventors: Robert Van Leeuwen, Ewing, NJ (US); Bing XU, Bayside, NY (US); Qing Wang, Plainsboro, NJ (US); Chuni Ghosh, West Windsor, NJ (US)

(73) Assignee: RealD Inc., Beverly Hills, CA (US)

(21) Appl. No.: 13/857,810

(22) Filed: Apr. 5, 2013

Related U.S. Application Data
(63) Continuation-in-part of application No. 13/764,770, filed on Feb. 11, 2013.
(60) Provisional application No. 61/621,067, filed on Apr. 6, 2012.

(51) Int. Cl. H01S 5/42; H01S 5/06

(52) U.S. Cl. CPC H01S 5/423; H01S 5/0605
USPC 372/22

(57) ABSTRACT

Disclosed herein are architectures for an external cavity laser. In some embodiments, the external cavity laser includes vertical cavity surface emitting laser (VCSEL) elements, a Brewster plate, frequency doubling chips, and a microlens array. The Brewster plate is arranged at an angle relative to the light path, and is configured to polarize at least the light received from the VCSELs and propagating on the light path in a first direction, and extract, from the external cavity, frequency-doubled light propagating on the light path in a second direction opposite to the first direction. The doubling chips are operable to receive the light and double the frequency of a portion of the received light. The microlens array is aligned with the VCSEL elements. A mount may be employed to mount the side stack of doubling chips by either side mounting or end mounting.

### CROSS-REFERENCE TO RELATED APPLICATIONS

This application is a non-provisional of and claims priority to U.S. Provisional Patent Application No. 61/621,067, entitled “Laser architectures”, filed Apr. 6, 2012 and is a continuation-in-part of and claims priority to U.S. patent application Ser. No. 13/764,770, entitled “Laser architectures”, filed Feb. 11, 2013, both of which are herein incorporated by reference in their entirety for all purposes.

### TECHNICAL FIELD

The present disclosure generally relates to lasers, and more specifically, to high power infrared laser technologies and components including solid state lasers, vertical cavity surface emitting lasers, and diodes.

### BACKGROUND

Generally, red, green, blue and ultraviolet (UV) lasers have many potential uses in illumination, medical, material processing, welding, and display. Cost, reliability, efficiency, size, and power are laser parameters that may be considered when selecting a laser for use in these various markets/technology fields. Display is an example of a market that has a number of different segments that value these parameters in slightly different ways. In the consumer display market, cost, efficiency, and size may be important parameters, while in the professional display market, reliability, high power, and cost may be key parameters. Cheap, reliable, highly efficient green, red, or blue sources are important for all the above applications. Such a green laser source is particularly relevant since high power direct sources, such as Vertical Cavity Surface Emitting Lasers (VCSELs) or edge emitting diodes, do not yet exist at the appropriate wavelengths for professional display applications.

Generally, a full color displays use at least red, green, and blue light sources. When employed in movie theaters, these colors have to be in certain ranges to comply with the standards set by the movie industry, and more specifically, with the Digital Cinema Initiative. The approximate accepted color ranges for movies are given by red or 616-650 nm, green or 523-545 nm, and blue or 455-468 nm. However, consumer display markets do not have such a strict wavelength requirement. As red and blue diodes have become available, interest in lasers for backlighting and use in consumer projectors has increased. Direct laser sources are cost effective, reliable, and efficient sources of light. However, currently there is no high power green direct laser source having the wavelength needed for display. Thus, green is an important laser technology, and there is a need in the art for a high power, efficient green direct source of light. In addition, red lasers currently have very severe cooling requirements and their lifetimes are relatively limited.

### SUMMARY

Disclosed herein are architectures for an external cavity laser. In exemplary embodiments, the external cavity laser includes vertical cavity surface emitting laser (VCSEL) elements, a Brewster plate, frequency doubling chips, and optionally a microlens array. Each VCSEL element provides infrared (IR) light on a light path in a first direction. The Brewster plate is arranged at an angle relative to the light path, and is configured to polarize at least the IR light propagating on the light path in the first direction, and extract, from the external cavity, frequency-doubled light propagating on the light path in a second direction opposite to the first direction. The doubling chips are operable to receive the IR light and double the frequency of a portion of the received IR light. The microlens array is aligned with the VCSEL elements, and operable to direct to and from the doubling chips. A mount may also be employed to mount the stack of doubling chips on either their side or on the ends of the doubling chips.

In specific embodiments, an architecture for an external cavity laser system in accordance with the disclosed principles may comprise at least two vertical cavity surface emitting laser (VCSEL) elements, each VCSEL element providing infrared (IR) light into a cavity on a light path in a first direction. Also, such an architecture may comprise at least two frequency doubling chips located in the cavity and configured to receive the IR light, and to substantially double the frequency of at least a portion of the received IR light. Further, an exemplary architecture may comprise an optical element at an end of the cavity opposite to the VCSEL elements and configured to be highly reflective to IR light, and a Brewster cut plate located between the VCSEL elements and the doubling chips, and arranged at an angle relative to the light path. In such embodiments, the Brewster plate may be configured to polarize at least the IR light propagating on the light path in the first direction, and extract, from the external cavity, frequency-doubled light propagating on the light path in a second direction opposite to the first direction.

In other, more specific embodiments, an architecture for an external cavity laser system in accordance with the disclosed principles may comprise a plurality of vertical cavity surface emitting laser (VCSEL) elements, each VCSEL element providing infrared (IR) light into a cavity on a light path in a first direction. Such architectures may also comprise a plurality of frequency doubling chips located in the cavity and configured to receive the IR light, and to substantially double the frequency of at least a portion of the received IR light. The plurality of doubling chips are typically arranged adjacent to one another, with spacers therebetween, into a stack. An exemplary architecture may further include a mount for holding the stack of doubling chips such that the IR light enters into edges of the doubling chips. A plurality of microlenses may also be located adjacent to the doubling chips and operable to direct light to and from the doubling chips. An optical element at an end of the cavity opposite to the VCSEL elements and configured to be highly reflective to IR light may also be provided. Moreover, exemplary architectures may further comprise a Brewster plate located between the VCSEL elements and the doubling chips, and arranged at an angle relative to the light path. In such embodiments, the Brewster plate may be configured to polarize at least the IR light propagating on the light path in the first direction, and extract, from the external cavity, frequency-doubled light propagating on the light path in a second direction opposite to the first direction.

### BRIEF DESCRIPTION OF THE DRAWINGS

Embodiments are illustrated by way of example in the accompanying figures, in which like reference numbers indicate similar parts, and in which:

FIG. 1 is a schematic diagram illustrating one embodiment of a conventional VCSEL-based device;

FIG. 2 is a schematic diagram illustrating an exemplary cavity using VCSEL arrays, in accordance with the disclosed principles;

FIG. 3 is a schematic diagram illustrating dual beam extraction from an exemplary cavity using VCSEL arrays, in accordance with the disclosed principles.

FIG. 4 is a schematic diagram illustrating a close up of periodically poled lithium niobate crystal (PPLN) stacks of chips with each having a slight spacing, in accordance with the disclosed principles;

FIG. 5 is a schematic diagram illustrating an exemplary lenslet array, in accordance with the disclosed principles;

FIG. 6 is a schematic diagram illustrating a perspective view of an end mounted doubling material stack and the direction of incoming light, in accordance with the disclosed principles;

FIG. 7 is a schematic diagram illustrating a top view of the end mounted doubler stack, in accordance with the disclosed principles;

FIG. 8 is a schematic diagram illustrating a bottom view of the mount shown in FIG. 7, in accordance with the disclosed principles;

FIG. 9 is a schematic diagram illustrating a perspective view of a side mounted doubling material stack and the direction of incoming light, in accordance with the disclosed principles; and

FIG. 10 is a schematic diagram illustrating an embodiment of a VCSEL based device, in accordance with the disclosed principles.

### DETAILED DESCRIPTION

Generally, there are several approaches to green/blue/red lasers. For very low power applications in which the wavelength of the light is not as critical, direct diodes in the approximate range of 50-100 mW are available in the appropriate wavelength ranges. For example, these diodes are of interest in small, mobile, “pico” projectors for the consumer market. However, for high power applications these sources are not useful. For higher power applications, conventional approaches typically employ infrared wavelengths generated by a solid state laser and then doubled with a non-linear crystal. Typical examples may include the doubling of fiber lasers and solid state lasers using crystals and doped glasses, for example, the YAG laser, that are lamp or diode pumped. These lasers may generate high power, good quality IR light which can be doubled. High intensity and good quality are critical for efficient doubling of the IR light to make visible or UV light, for example, 1064 nm doubled to 532 nm (green light), while 1232 nm can be doubled to 616 nm (red light). While these current doubled solid state sources can generate a lot of power in the green wavelength, in the approximate range of a few Watts to thousands of Watts, solid state sources are expensive, complex, not very efficient, and are difficult to make reliable. For example, approximately 30,000 hours or more are commonly needed for professional display applications for which approximately 5 to 2000 Watts of visible light may be appropriate.

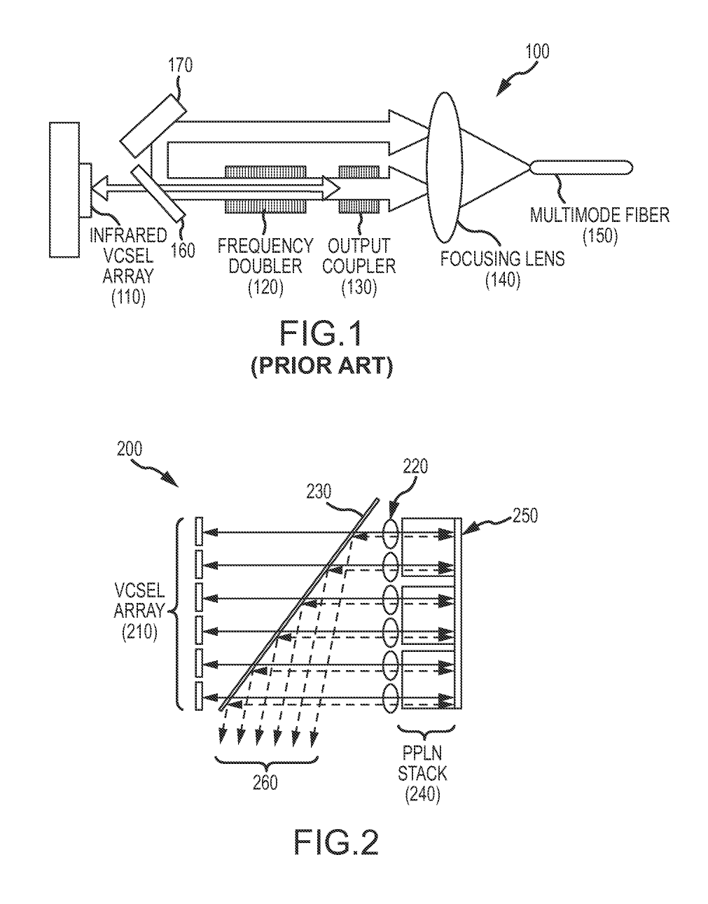

Another version of green or blue laser that has been produced uses a VCSEL array, such as the exemplary embodiment of a VCSEL array illustrated in FIG. 1. FIG. 1 is a schematic diagram illustrating one embodiment of a conventional VCSEL-based device 100. Unfortunately, VCSEL elements themselves do not typically output the appropriate power needed for preferred applications such as those identified above. For example, a VCSEL may output approximately 150 mW or less, and in the example of a VCSEL array have a spread of wavelengths, for example, greater than the approximate range of one to ten nanometers. Thus, a typical low power VCSEL element or VCSEL array may be difficult to efficiently frequency double with conventional architectures. The advantage of their use, however, is that VCSELs are extremely reliable and produce good quality IR light.

Before proceeding to the disclosed embodiments in detail, it should be understood that the illustrated embodiments discussed herein are not limited in application or creation to the details of the particular arrangements shown, because the embodiments are capable of other arrangements. Moreover, aspects of the embodiments may be set forth in different combinations and arrangements to define embodiments unique in their own right. Also, the terminology used herein is for the purpose of description and not of limitation.

FIG. 1 illustrates a diagram of such a VCSEL-based device 100 from Necsel/Ushio that is commercially available. The VCSEL device 100 includes an infrared VCSEL array 110, a PPLN frequency doubler 120, a special output coupler (a volume Bragg grating (VBG) in this embodiment) 130, a focusing lens 140, and a multimode fiber 150 to carry the output light. Light illuminated from the VCSEL array 110 initially passes through a dichroic mirror 160. A first path passes through dichroic mirror 160 to illuminate a frequency doubler 120 for doubling the frequency of the light. That light then passes to the volume Bragg grating (VBG) 130, which functions as an output coupler in this embodiment. This type of output coupler is required in conventional architectures to reduce the spread of frequency in the cavity so that the lower power elements can be doubled by a long and very sensitive (but efficient) periodically poled doubling crystal 120. The long length of the doubler 120 in the (>4 mm) requires the use of the VBG 130 to be used to tighten the spread of IR frequencies in the cavity and lock them to the best frequency for the periodically poled doubler 120. Both the long periodically poled doubler 120 and the VBG output coupler 130 have very tight tolerances for wavelength, temperature and alignment, and therefore detrimentally affect the cost and reliability of the whole laser. The VBG 130 reflected the IR light of a limited frequency so that it can pass back through the doubler 120 and which then converts some more of the IR light to the doubled frequency, which is then reflected by the dichroic mirror 160 and then reflected toward the focusing lens 140 by mirror 170. Focusing lens 140 and mirror 170 are not considered inside the cavity. The focusing lens 140 focuses the first and second paths into the multimode fiber 150, which can then pass from the device 100 for use to illuminate an image. The focusing lens 140 and fiber 150 are not necessary, however, as free space beam output can also be desired.

Looking specifically at the light on the first path which is being doubled, the frequency doubler 120 may comprise a periodically poled lithium niobate crystal (PPLN) as mentioned above, wherein PPLN may be employed rather than a bulk doubling crystal because it may be more efficient at doubling the frequency of the light. This may be employed due to the lower intensities of the VCSEL beams. However, long lengths of PPLN may have a number of significant concerns. First, it may be more expensive than a bulk doubling crystal. Second, in order for PPLN to work well it has very tight tolerances on alignment, wavelength of IR light, and temperature. Thus, the PPLN has to be actively temperature controlled to approximately 0.1 degree Celsius or so, depending on the length of the crystal. Such a tight temperature control system is expensive and is challenging from a reliability point of view.

The wavelength spread that the PPLN can double effectively is also very challenging. Depending on length of the PPLN this can be as little as 0.1 nm, typically. This tight tolerance typically requires the use of a wavelength control device, such as a VBG in the cavity as described in the conventional architecture of FIG. 1, so that all the elements of the array can be effectively doubled. Typically, the appropriate narrow bandwidth may indicate that a simple etalon may not be used to narrow the bandwidth. Consequently, a difficult to fabricate volume Bragg grating is typically employed as the output coupler 130. In volume manufacturing, this volume grating can be the most expensive element in the optical system. Both the PPLN and the VBG have tight angular tolerances as well, making volume manufacturing of the overall structure and operation over temperature changes difficult to achieve. As such, low power devices of a few watts have been made using this approach, but manufacturing such devices for high power applications is far more problematic.

Princeton Optronics of Mercerville, N.J., has been able to manufacture VCSELs with unique properties. The individual VCSEL elements can exhibit high power, for example, greater than approximately 150 mW; are very reliable, for example, greater than 100,000 hours; and have good optical quality, which may include microlenses fabricated on the VCSEL elements for improving energy capture. The VCSELs and corresponding properties are generally discussed in U.S. Pat. No. 6,888,871, “VCSEL and VCSEL Array Having Integrated Microlenses For Use In A Semiconductor Laser Pumped Solid State System” and “High Power VCSEL Mature Into Production”, Laser Focus World, April 2011, pp. 61-65, both of which are herein incorporated by reference in their entirety for all purposes. See also, commonly-assigned U.S. Provisional Patent Application Serial. No. 61/598,175, entitled “Laser architectures,” filed Feb. 13, 2012, as well as its nonprovisional conversion U.S. patent application Ser. No. 13/764,770, both of which are herein incorporated by reference in their entirety for all purposes.

Using high power VCSEL elements either single or in array that the reflectivity of the output distributed Bragg reflector (DBR) designed to increase the power in an external cavity (rather than the power in the VCSEL laser), and use a short section of PPLN doubler that will be mounted uniquely for temperature control. The high power of the individual elements >200 mW allow for shorter, for example, <6 mm, PPLN length to be used. In addition to short length, the PPLN can comprise multiple sections that can then be better temperature controlled. The short length increases the laser's reliability, and has eased manufacturing and alignment tolerances. There are a number of cavity architectures that can be used to double the IR light. The VCSEL can be single elements, or arrays with high intensity elements. These arrays are designed for high power and have the output DBR set to increase power in the external cavity, which is outlined by the disclosed principles as being between the VCSEL element(s) and a frequency-dependent highly reflective/anti-reflective (HR/AR) or highly reflective/highly reflective (HR/HR) (depending on the application, as described in further detail below) structure immediately following the bulk doubling material. In addition, the flatness of the 2D array is critical and the radius of curvature should be greater than 5 m for good performance.

FIG. 2 is a schematic diagram illustrating an exemplary cavity architecture 200 using a VCSEL array, in accordance with the disclosed principles. The individual 2D or 1D arrayed VCSEL elements 210 may be high power elements. Additionally, the VCSEL elements may have lenslets or microlenses 220 positioned in the cavity for better beam quality. In addition, their output reflectivity may be optimized to increase the power in the external cavity of the laser.

In the cavity architecture 200 of FIG. 2, there may be a coated etalon which in one embodiment may be a Brewster plate 230 that is anti-reflective (AR) coated for infrared (IR) light and highly reflective (HR) coated for green or blue depending on whether a green or blue laser is desired. The wavelength of 1064 nm and 532 nm are used as representative wavelength for IR and green/blue respectively. However, IR can easily span 800-1200 nm and green/blue can span 400-600 nm. The Brewster plate 230 may be employed to improve the polarization state of the beam and allow for the green/blue beam to be extracted from the cavity. The beams are then incident on a stack 240 of frequency doubling material, such as short PLLN doublers that cover individual VCSEL element output or multiple VCSEL element outputs. The PPLN doublers in the stack 240 are mounted to allow for better temperature control of the PPLN. Moreover, the microlens array 220 may be positioned adjacent to the doublers 240 in order to help focus the light generated from the VCSEL array 210 and thus provide higher quality beams entering the PPLN doubler stack 240. Moreover, the frequency doubler chips in the stack 240 may alternatively be comprised of barium borate, potassium dihydrogen phosphate, potassium titanyl phosphate, lithium triborate, or potassium niobate, in addition to lithium niobate. Of course, other advantageous frequency doubling materials may also be employed in accordance with the disclosed principles.

The opposite sides, for example, opposite of the VCSEL array 210, of the PPLN doublers of the stack 240 are coated in this embodiment with a highly reflective (HR) coating 250 for both IR and green/blue, as illustrated. The light then passes back through the PPLN doubler stack 240 again (creating more green/blue light) and then the green light 260 is extracted by the Brewster plate 230, which is highly reflective to green light wavelengths. Depending on the embodiment, the HR coating 250 may be on the PPLN or other doubling material itself or it may be on a separate optical element, in which the optical element may be reflective and adjacent or proximate to the doubling material.

The VCSEL array 210 should be mounted carefully and both flatness of the array and temperature of the array controlled. The array's 210 flatness can be improved by considering the mounting configuration with respect to the mount or by how it is mounted to the mount. The array 210 can be stressed by force to make the array flatter as it is soldered to the mount. The array 210 should be flatter than a radius of curvature of about 5 mm or so. The force on the edges or center during the soldering process can improve flatness of the resulting array 210. This can be achieved in a number of ways including by pushing or pulling the substrate mechanically or with hanging weights. In addition, higher quality submounts that are flatter to start with can improve the resulting flatness of the VCSEL array on the overall mount. Typically, these submounts may be diamond for their heat conducting characteristics, but other materials can also be used, and these submounts are then placed on a heat sink or cooling mount. The flatter the submount(s), the easier it is to make the VCSEL array flat when mounted on the submount. No matter what approach is used, the temperature of the VCSEL array 210 should be controlled and the manufacturing of the array 210 such that the wavelength of the elements of the array 210 differ by less than 2 nm.

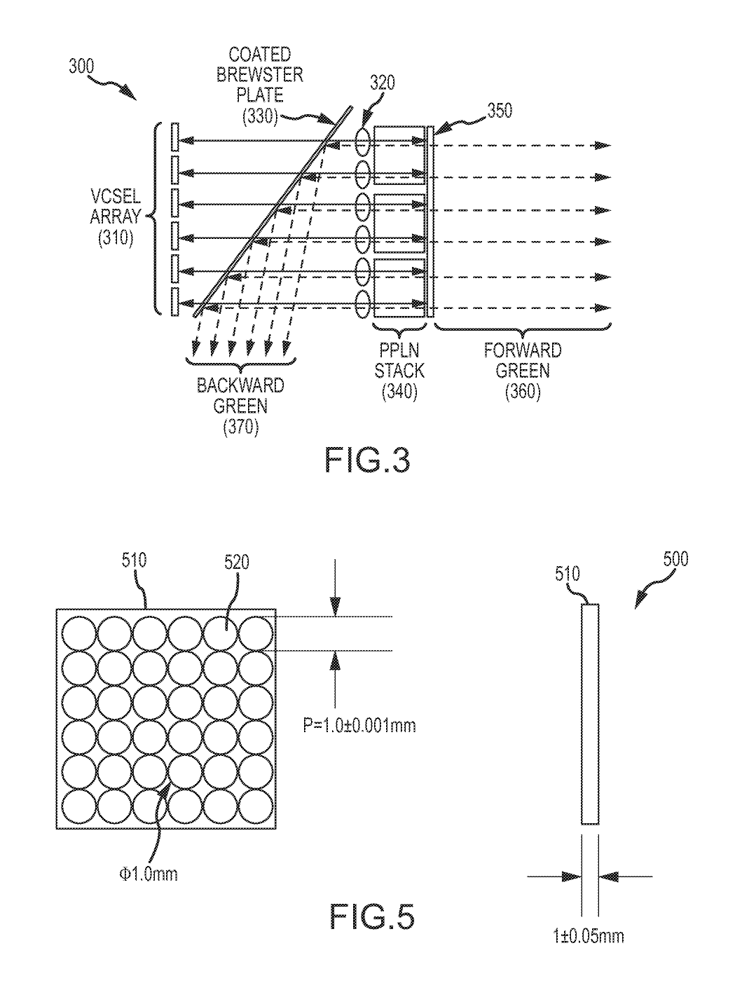

FIG. 3 is a schematic diagram illustrating one embodiment of a dual beam extraction technique in accordance with the disclosed principles. Once again, VCSEL elements are arranged in an array 310 for producing IR light. In the cavity architecture 300 of FIG. 3, a coated Brewster plate 330 that is anti-reflective (AR) coated for IR light and HR coated for green or blue light is also provided. The Brewster plate 330 may be employed to improve the polarization state of the beam and allow for the green/blue beam to be extracted from the cavity, as described above. Beams in the IR wavelengths transmitted from the VCSEL array 310 pass through the Brewster's plate 330 and are incident on a stack of doubling material 340, such as PPLN. Additionally, an array of microlenses 320 may again be used to focus the beams received from the VCSEL array 310. The doublers in the stack 340 are again mounted together to allow for better temperature control of the doubling material.

The opposite sides of the doubler material stack 340, for example the side of the doubler material stack opposite of the VCSEL array 310, may be coated with a coating 350 that is HR for IR wavelengths, but for green/blue light, the coating 350 would be anti-reflective. As before, depending on the embodiment, the HR/AR coating 350 may be on the doubler material itself or it may be on a separate optical element adjacent to the doubling material stack 340. Any green light that is forward propagating through the cavity passes through the HR/AR coating 350 as “forward” green light 360. IR exiting the doubler material stack 340 is reflected by the coating 350 and passes back through the PPLN doubler stack 340 again thereby creating more green/blue light. This “backwards” propagating green light 370 is extracted by the Brewster plate 330, which is highly reflective to green light wavelengths. The forward and backward green (or blue) light can be combined outside the cavity.

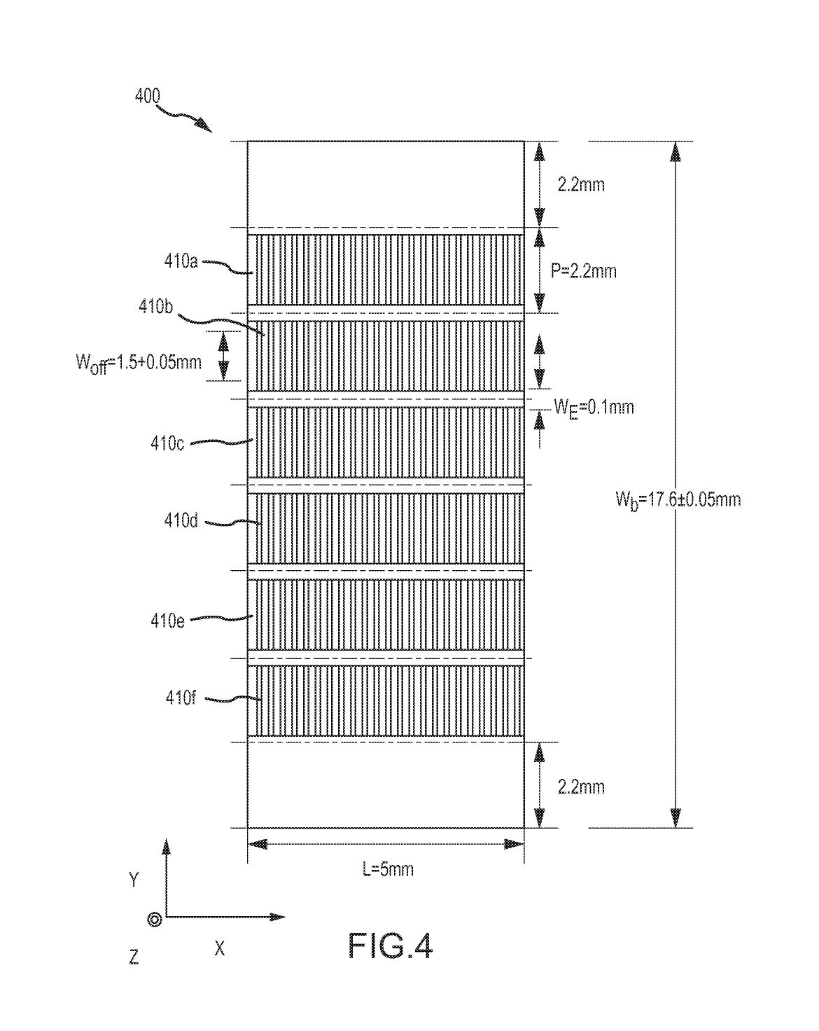

FIG. 4 is a schematic diagram illustrating a close up of PPLN frequency doubler stacks or chips. In the illustrated embodiment, six doublers (410a-410f) are provided in the stack, with each being spaced about 0.1 mm from the adjacent doubler (W_{c}=0.1 mm). The size of each of the PPLN doublers in the stack are determined by the VCSEL beam size at the stacks, and the VCSEL/microlens array spacings. As discussed herein, microlens array and lenslet array may be used interchangeably. These sizes may be changed to match the VCSEL array and the microlens array specifications for the size of the beams as they pass though the PPLN stacks. In the illustrated embodiment, the doubler have a length (L) of about 5 mm, and a uniform spacing (P) of about 2.2 mm. However, the effective width (W_{eff}) is less than the actual size of the doublers due to the beam size from the VCSEL array, and in this embodiment is about 1.5 to 2.0 mm. With additional spacing provided at each end of the stack (e.g., about 2.2 mm on each), the exemplary stack of doublers has an overall length (W_{b}) of about 17.6 mm.

FIG. 5 is a schematic diagram 500 illustrating front and sides views of an exemplary microlens lenslet array 510. In the illustrated embodiment, each of the microlenses 520 has an approximate size (P) of about 1.0 mm, with a thickness also of about 1.0 mm. The spacing (Φ) between the individual microlenses 520 within the array 510, which in this embodiment is about 1.0 mm, may be determined by the spacing of the VCSEL elements in the VCSEL array. The position and curvature of the array 510 may be set so that the beams from the VCSEL array pass through one microlens 520 per element and so that the microlens 520 either quasi collimates the beam or causes it to focus either near the middle of the PPLN stacks or at the high reflector. Accordingly, the VCSEL array's element layout and the microlens layout should substantially match. Thus, if the VCSEL array elements are laid out as hexagonal or rectilinear with respect to one another, then the microlenses 520 in the lenslet array 510 may also be laid out similarly.

Mounting the PPLN so that alignment and temperature control are facilitated are important criteria for volume manufacturing of doubler stacks as disclosed herein. Accordingly, the disclosed principles provide for at least two mounting techniques, end and side mounting, both of which are discussed in further detail below.

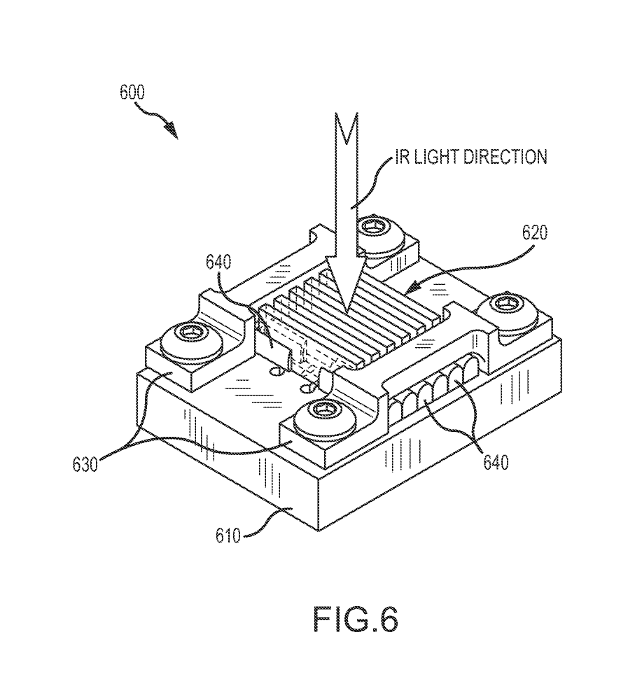

FIG. 6 illustrates a perspective view of a first embodiment of a mount 600 for a frequency doubler stack 620 according to the disclosed principles that is end-mounted on the mount. The direction of light entering the PPLN doubler stack 620 is also illustrated. The far ends of the PPLN stack 620 may have an HR coating (not illustrated) on it. As shown and described with reference to FIG. 4, the PPLN chips 620 may be separated from one another for better cooling. Mounting arms 630 may be used to hold the PPLN doublers 620 directly, or, as illustrated, individual end couplers 640 may be used as thermally conductive submounts to secure each doubler material independently. Also, the mounting arms 630 securing the doubler stack 620 to the base 610 may be constructed of a thermally conductive material, such as copper. As a result, the mounting arms 630 assist in conducting heat away from the PPLN chips 620. The whole mount 600 may advantageously be cooled by a thermal electric (TE) cooler (not illustrated) or air flow, or, alternatively, each PPLN doubler in the stack 620 can be temperature controlled. Furthermore, a temperature sensor can be incorporated in the mount 600, if desired.

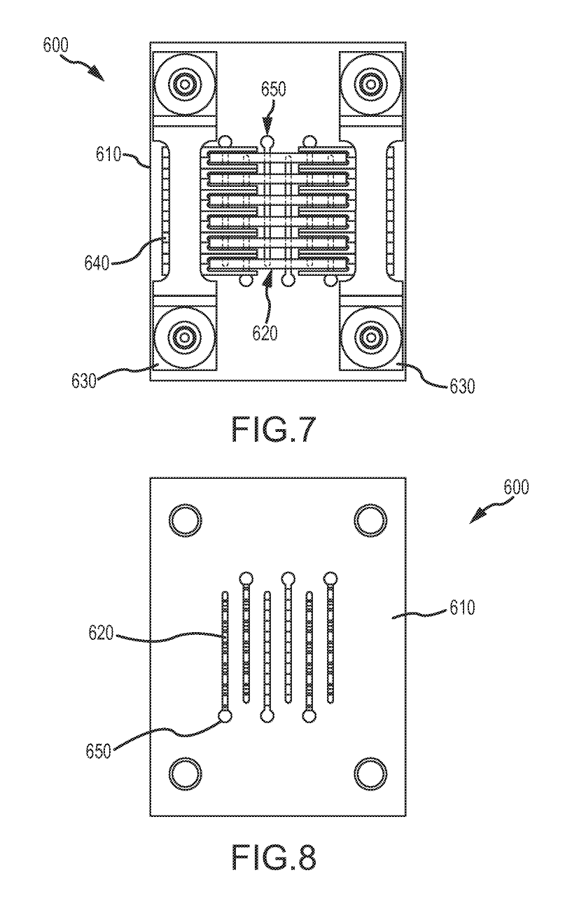

FIG. 7 is a schematic diagram illustrating a top view of the end mount PPLN stack mount 600 introduced in FIG. 6. From the top view, the doubler material stack 620 can be visible, as well as the mounting arms 630 and couplers 640 used to the secured the doubler stack 620 to the mount base 610. From this view, slots 650 in the base 610 of the mount 600 can be visible, and may be employed to let light exit the doubler stack 620 in the direction of the slots 640, depending on the embodiment and construction of the VCSEL based device.

FIG. 8 is a schematic diagram illustrating a bottom view of the mount 600 shown in FIGS. 6 and 7. From this view, the light exit slots 650 are more easily visible. In the illustrated embodiment, the slots 650 are shown offset in their layout, however, they can be centered or even more offset, as desired, as long as they substantially cover the doubler material chips in the stack 620. Moreover, the slots 650 may be sized to accommodate the beams from the VCSEL array.

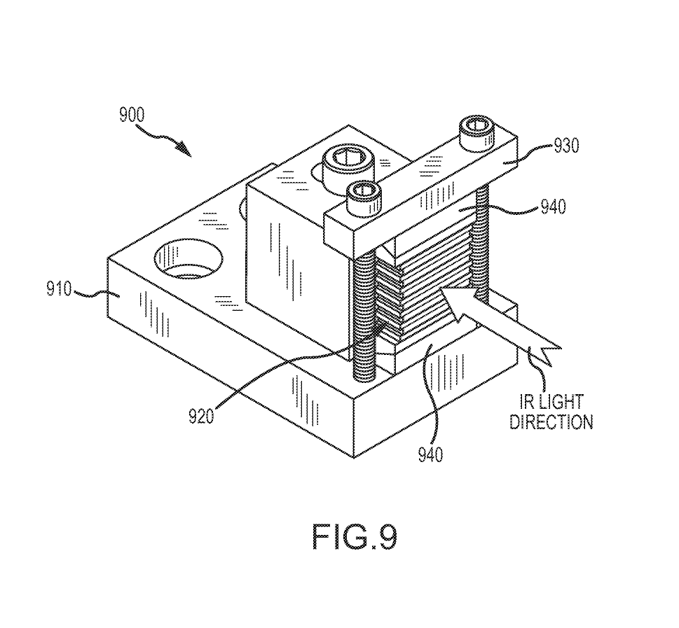

An alternative manner of mounting a stack of doubler material 920 in accordance with the disclosed principles is to hold the doublers 920 on their sides. FIG. 9 is a schematic diagram showing one embodiment of a side-mounted technique for mounting the doubler material stack 920 in a mount 900. The whole mount assembly 900 is pressed together from the top using a mounting arm 930, which connects to the base 910 of the mount 900. The mounting arms 930 contact the stack 920 via thermally conductive submounts or couplers 940. As shown by the arrow, the IR light enters the doubler stack 920 from outside the mount 900. Also as before, the far end of the doubler material stack 920 (opposite from the side of the incoming IR light) may be HR coated as described in detail above. As in other embodiments, the doubler material 920 may be PPLN chips, and may be separated by spacers. Advantageously, the spacers may be thermally conductive and thus used, in combination with the couplers 940, to conduct heat from the doubler material chips 920 and to the mount 900 for more effective heat dissipation and thus temperature control of the stack 920.

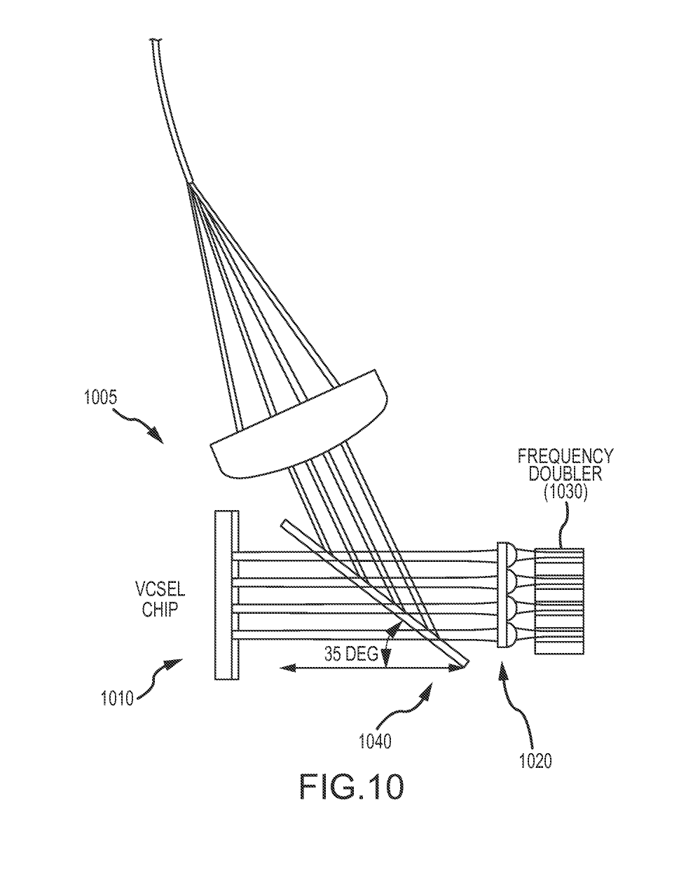

FIG. 10 is a schematic diagram illustrating an embodiment of a VCSEL based device 1005. FIG. 10 includes a VCSEL array 1010. The VCSEL array may be a 1D or 2D array. Also illustrated in FIG. 10, are a lenslet array 1020 and a doubler 1030. The doubler 1030 may be any appropriate doubler including, but not limited to, a bulk doubler, a PPLN doubler, and so forth. The doubler may have a highly reflective coated surface that reflects at least one of or both of IR and green/blue light. Also included in FIG. 10 is an etalon 1040 that has a highly reflective coating for green/blue light and that may also substantially remove green/blue light out of the cavity to be substantially collimated or focused into a fiber. In one embodiment, a separate mirror element may be employed instead of or in addition to the highly reflective coated surface for the doubler. The etalon is illustrated at approximately 35 degrees, but can be tilted near or at the Brewster angle. Although the lenslet array is included in FIG. 10, it is an optional element.

In one example and continuing the discussion of FIG. 10, light may be introduced to the VCSEL based device 1005 by the VCSEL chip 1010 and be passed through the etalon 1040. The light may then pass through the lenslet array 1020 and encounter the doubler 1030. The doubler 1030 may reflect IR and/or green/blue light back through the doubler 1030 and the lenslet array 1020. The IR and/or green/blue light may then encounter the etalon 1040 and the etalon may reflect the green/blue light out and the green/blue light may be coupled into a fiber.

As may be used herein, the terms “substantially” and “approximately” provide an industry-accepted tolerance for its corresponding term and/or relativity between items. Such an industry-accepted tolerance ranges from less than one percent to ten percent and corresponds to, but is not limited to, component values, angles, et cetera. Such relativity between items ranges between less than one percent to ten percent.

It should be noted that embodiments of the present disclosure may be used in a variety of optical systems and projection systems. Exemplary embodiments may include or work with a variety of projectors, projection systems, optical components, computer systems, processors, self-contained projector systems, visual and/or audiovisual systems, and electrical and/or optical devices. Aspects of the present disclosure may be used with practically any apparatus related to optical and electrical devices, optical systems, display systems, presentation systems or any apparatus that may contain any type of optical system. Accordingly, embodiments of the present disclosure may be employed in optical systems, devices used in visual and/or optical presentations, visual peripherals and so on and in a number of computing environments including the Internet, intranets, local area networks, wide area networks and so on.

While various embodiments in accordance with the principles disclosed herein have been described above, it should be understood that they have been presented by way of example only, and not limitation. Combinations of these architectures and cavity elements can be used as understood by one skilled in the art. Thus, the breadth and scope of this disclosure should not be limited by any of the above-described exemplary embodiments, but should be defined only in accordance with any claims and their equivalents issuing from this disclosure. Furthermore, the above advantages and features are provided in described embodiments, but shall not limit the application of such issued claims to processes and structures accomplishing any or all of the above advantages.

Additionally, the section headings herein are provided for consistency with the suggestions under 37 C.F.R. 1.77 or otherwise to provide organizational cues. These headings shall not limit or characterize the invention(s) set out in any claims that may issue from this disclosure. Specifically and by way of example, although the headings refer to a “Technical Field,” the claims should not be limited by the language chosen under this heading to describe the so-called field. Further, a description of a technology in the “Background” is not to be construed as an admission that certain technology is prior art to any embodiment(s) in this disclosure. Neither is the “Summary” to be considered as a characterization of the embodiment(s) set forth in issued claims. Furthermore, any reference in this disclosure to “invention” in the singular should not be used to argue that there is only a single point of novelty in this disclosure. Multiple embodiments may be set forth according to the limitations of the multiple claims issuing from this disclosure, and such claims accordingly define the embodiment(s), and their equivalents, that are protected thereby. In all instances, the scope of such claims shall be considered on their own merits in light of this disclosure, but should not be constrained by the headings set forth herein.

What is claimed is:

1. An architecture for an external cavity laser system, the architecture comprising:
at least two vertical cavity surface emitting laser (VCSEL) elements, each VCSEL element providing infrared (IR) light into a cavity on a light path in a first direction;
at least two frequency doubling chips located in the cavity and configured to receive the IR light, and to substantially double the frequency of at least a portion of the received IR light;
an optical element at an end of the cavity opposite to the VCSEL elements and configured to be highly reflective to IR light; and
a Brewster plate located between the VCSEL elements and the doubling chips, and arranged at an angle relative to the light path, wherein the Brewster plate is configured to:
extract, from the external cavity, frequency-doubled light propagating on the light path in a second direction opposite to the first direction.

2. The architecture of claim 1, wherein frequency doubled light comprises visible light selected from at least one of red, green, blue, or ultraviolet light.

3. The architecture of claim 1, wherein the optical element comprises a coating located on surfaces of the frequency doubling chips at an end of the cavity opposite to the VCSEL elements.

4. The architecture of claim 1, wherein the optical element is highly reflective to both the IR light and light in the visible spectrum.

5. The architecture of claim 1, wherein the optical element is anti-reflective to light in the visible spectrum.

6. The architecture of claim 1, further comprising a plurality of microlenses located adjacent to, and corresponding to the number of, the doubling chips, wherein the microlenses are operable to direct light to and from the doubling chips.

7. The architecture of claim 1, wherein the doubling chips comprise crystals selected from at least one of barium borate, potassium dihydrogen phosphate, potassium titanyl phosphate, lithium niobate, lithium triborate, and potassium niobate.

8. The architecture of claim 1, wherein the doubling chips are arranged adjacent to one another, with spacers therebetween, into a stack, the architecture further comprising a mount for holding the stack of doubling chips such that the IR light enters into edges of the doubling chips.

9. The architecture of claim 8, wherein the stack of doubling chips are positioned on the mount on a side surface of a doubling chip located at an end of the stack.

10. The architecture of claim 8, wherein the stack of doubling chips are positioned on the mount on edges of the doubling chips in the stack.

11. The architecture of claim 10, further comprising slots formed through the mount for passing light therethrough, wherein locations of the slots substantially align with at least some of the edges of the doubling chips.

12. The architecture of claim 8, wherein the spacers are operable to dissipate heat from the doubling chips to at least a portion of the mount.

13. The architecture of claim 1, wherein the at least two VCSEL elements comprise an array, and wherein the array is flatter than a radius of curvature of 5 mm.

14. An architecture for an external cavity laser system, the architecture comprising:
a plurality of vertical cavity surface emitting laser (VCSEL) elements, each VCSEL element providing infrared (IR) light into a cavity on a light path in a first direction;
a plurality of frequency doubling chips located in the cavity and configured to receive the IR light, and to substantially double the frequency of at least a portion of the received IR light, wherein the plurality of doubling chips are arranged adjacent to one another, with spacers therebetween, into a stack;
a mount for holding the stack of doubling chips such that the IR light enters into edges of the doubling chips;
a plurality of microlenses located adjacent to the doubling chips and operable to direct light to and from the doubling chips;
an optical element at an end of the cavity opposite to the VCSEL elements and configured to be highly reflective to IR light; and
a Brewster plate located between the VCSEL elements and the doubling chips, and arranged at an angle relative to the light path, wherein the Brewster plate is configured to:
polarize at least the IR light propagating on the light path in the first direction, and
extract, from the external cavity, frequency-doubled light propagating on the light path in a second direction opposite to the first direction.

15. The architecture of claim 14, wherein frequency doubled light comprises visible light selected from at least one of red, green, blue, or ultraviolet light.

16. The architecture of claim 14, wherein the optical element comprises a coating located on surfaces of the frequency doubling chips at an end of the cavity opposite to the VCSEL elements.

17. The architecture of claim 14, wherein the optical element is highly reflective to both the IR light and light in the visible spectrum.

18. The architecture of claim 14, wherein the optical element is anti-reflective to light in the visible spectrum.

19. The architecture of claim 14, wherein the number of microlenses corresponds to or is greater than the number of doubling chips.

20. The architecture of claim 14, wherein the doubling chips comprise crystals selected from at least one of barium borate, potassium dihydrogen phosphate, potassium titanyl phosphate, lithium niobate, lithium triborate, and potassium niobate.

21. The architecture of claim 14, wherein the stack of doubling chips are positioned on the mount on a side surface of a doubling chip located at an end of the stack.

22. The architecture of claim 14, wherein the stack of doubling chips are positioned on the mount on edges of the doubling chips in the stack,

23. The architecture of claim 14, wherein the at least two VCSEL elements comprise an array, and wherein the array is flatter than a radius of curvature of 5 mm.

24. An architecture for an external cavity laser system, the architecture comprising:
an array of vertical cavity surface emitting laser (VCSEL) elements, each VCSEL element providing infrared (IR) light into a cavity on a light path in a first direction, wherein the array is flatter than a radius of curvature of 5 mm;
a stack of frequency doubling chips separated by spacers, the stack located in the cavity and configured to receive the IR light, and to substantially double the frequency of at least a portion of the received IR light;
a mount for holding the stack of doubling chips such that the IR light enters into edges of the doubling chips, wherein the spacers are thermally coupled to the mount for dissipating heat from the doubling chips;
a plurality of microlenses located adjacent to the doubling chips and operable to direct light to and from the doubling chips;
an optical element at an end of the cavity opposite to the array and configured to be highly reflective to IR light; and
a Brewster plate located between the array and the doubling chips, and arranged at an angle relative to the light path, wherein the Brewster plate is configured to:
polarize at least the IR light propagating on the light path in the first direction, and
extract, from the external cavity, frequency-doubled light propagating on the light path in a second direction opposite to the first direction.

25. The architecture of claim 24, wherein frequency doubled light comprises visible light selected from at least one of red, green, blue, or ultraviolet light.

26. The architecture of claim 24, wherein the optical element comprises a coating located on surfaces of the frequency doubling chips at an end of the cavity opposite to the array.

27. The architecture of claim 24, wherein the optical element is highly reflective to both the IR light and light in the visible spectrum.

28. The architecture of claim 24, wherein the optical element is anti-reflective to light in the visible spectrum.

29. The architecture of claim 24, wherein the stack is positioned on the mount on a side surface of a doubling chip located at an end of the stack.

30. The architecture of claim 24, wherein the stack is positioned on the mount on edges of the doubling chips in the stack.

31. The architecture of claim 1, wherein the Brewster plate is configured to polarize at least the IR light propagating on the light path in the first direction.
